(19) United States
(12) Patent Application Publication
(10) Pub. No.: US 2016/0301882 A1
(43) Pub. Date: Oct. 13, 2016

(54) SOLID-STATE IMAGING DEVICE AND METHOD OF MANUFACTURING THE SOLID-STATE IMAGING DEVICE

(71) Applicant: KABUSHIKI KAISHA TOSHIBA, Tokyo (JP)

(72) Inventors: Hirofumi YAMASHITA, Kawasaki Kanagawa (JP); Hiroki SASAKI, Yokohama Kanagawa (JP)

(73) Assignee: KABUSHIKI KAISHA TOSHIBA, Tokyo (JP)

(21) Appl. No.: 14/741,863

(22) Filed: Jun. 17, 2015

(30) Foreign Application Priority Data
Apr. 9, 2015 (JP) 2015-080232

(51) Int. Cl. H04N 5/363; H01L 27/146

(52) U.S. Cl. CPC H04N 5/363; H01L 27/14665; H01L 27/14605; H01L 27/14689

(57) ABSTRACT

According to one embodiment, a solid-state imaging device comprises a photoelectric conversion film provided over a semiconductor substrate; a storing electrode provided under part of the photoelectric conversion film; an insulating film provided under the photoelectric conversion film so as to cover a top and a side wall of the storing electrode; a transfer electrode provided between the other part of the photoelectric conversion film and the insulating film; and an upper electrode provided on the photoelectric conversion film.

### CROSS-REFERENCE TO RELATED APPLICATIONS

This application is based upon and claims the benefit of priority from Japanese Patent Application No. 2015-80232, filed on Apr. 9, 2015; the entire contents of which are incorporated herein by reference.

### FIELD

Embodiments described herein relate generally to a solid-state imaging device and method of manufacturing the solid-state imaging device.

### BACKGROUND

Among solid-state imaging devices, there are ones in which a photoelectric conversion film is laid over a semiconductor substrate having a signal readout circuit provided therein in order to improve the sensitivity. For these, there exists a method which provides a storing electrode under the photoelectric conversion film to store charge, photoelectrically converted into in the photoelectric conversion film, in the photoelectric conversion film in order to reduce kTC noise.

### BRIEF DESCRIPTION OF THE DRAWINGS

FIG. 1A is a cross-sectional view showing schematically the configuration of a pixel of a solid-state imaging device according to a first embodiment, and FIG. 1B is a diagram showing potential distributions at storage and at transfer in a photoelectric conversion film of FIG. 1A;

FIG. 2 is a diagram showing the circuit configuration of the pixel of the solid-state imaging device according to the first embodiment;

FIGS. 3A to 3D are cross-sectional views showing a manufacturing method for pixels of a solid-state imaging device according to a second embodiment;

FIGS. 4A to 4C are cross-sectional views showing the manufacturing method for pixels of the solid-state imaging device according to the second embodiment;

FIGS. 5A and 5B are cross-sectional views showing the manufacturing method for pixels of the solid-state imaging device according to the second embodiment;

FIG. 6 is a cross-sectional view showing schematically the configuration of a pixel of a solid-state imaging device according to a third embodiment;

FIG. 7A is a diagram showing the circuit configuration of the pixel of the solid-state imaging device according to the third embodiment, and FIGS. 7B1 and 7B2 are diagrams showing other circuit configurations of the pixel of the solid-state imaging device according to the third embodiment;

FIG. 8 is a cross-sectional view showing schematically the configuration of a pixel of a solid-state imaging device according to a fourth embodiment;

FIG. 9 is a cross-sectional view showing schematically the configuration of a pixel of a solid-state imaging device according to a fifth embodiment;

FIG. 10 is a cross-sectional view showing schematically the configuration of a pixel of a solid-state imaging device according to a sixth embodiment;

FIG. 11 is a cross-sectional view showing schematically the configuration of a pixel of a solid-state imaging device according to a seventh embodiment;

FIGS. 12A to 12E are cross-sectional views showing a manufacturing method for pixels of a solid-state imaging device according to an eighth embodiment; and

FIGS. 13A to 13D are cross-sectional views showing the manufacturing method for pixels of the solid-state imaging device according to the eighth embodiment.

### DETAILED DESCRIPTION

According to one embodiment, a solid-state imaging device comprises a photoelectric conversion film provided over a semiconductor substrate; a storing electrode provided under part of the photoelectric conversion film; an insulating film provided under the photoelectric conversion film so as to cover a top and a side wall of the storing electrode; a transfer electrode provided between the other part of the photoelectric conversion film and the insulating film; and an upper electrode provided over the photoelectric conversion film.

The solid-state imaging devices and methods of manufacturing the solid-state imaging devices according to embodiments will be described in detail below with reference to the accompanying drawings. The present invention is not limited to these embodiments.

### First Embodiment

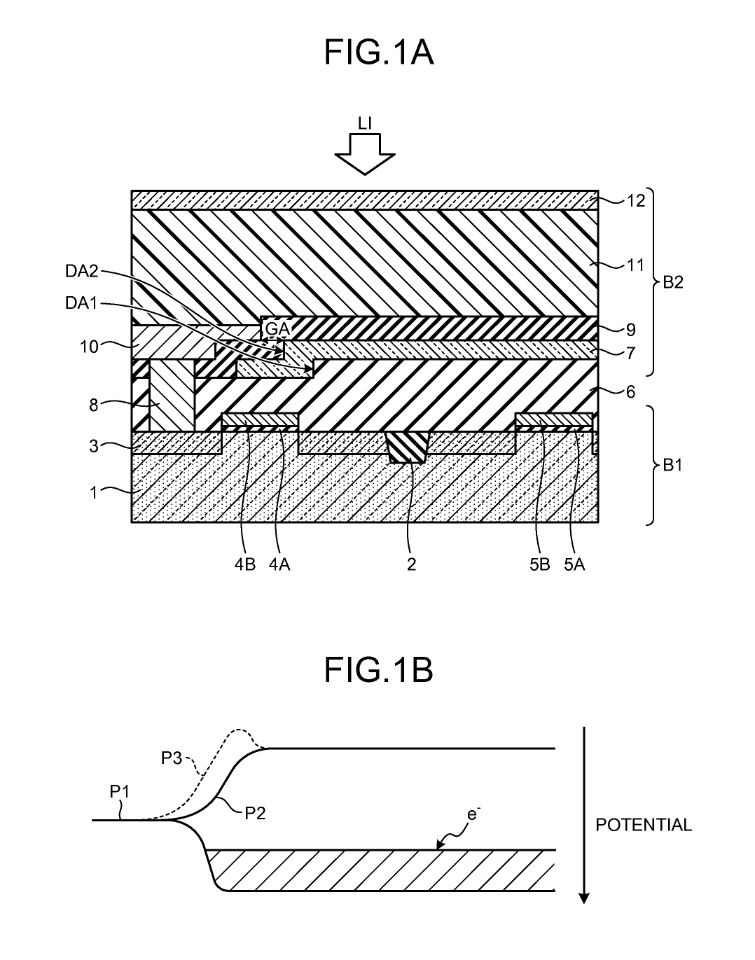

FIG. 1A is a cross-sectional view showing schematically the configuration of a pixel of a solid-state imaging device according to the first embodiment, and FIG. 1B is a diagram showing potential distributions at storage and at transfer in a photoelectric conversion film of FIG. 1A. P1 of FIG. 1B indicates the potential distribution of the photoelectric conversion film 11 when charge is stored; P2 indicates the potential distribution of the photoelectric conversion film 11 when charge is transferred with a gap GA being small; and P3 indicates the potential distribution of the photoelectric conversion film 11 when charge is transferred with a gap GA being large.

In FIG. 1A, a signal readout circuit B1 and a photoelectric conversion unit B2 are provided in the solid-state imaging device. The photoelectric conversion unit B2 is laid over the signal readout circuit B1. The signal readout circuit B1 comprises a semiconductor substrate 1. An STI (Shallow Trench Isolation) 2 is formed in the semiconductor substrate 1, so that active regions are separated. As the material for the semiconductor substrate 1, for example, Si, Ge, SiGe, GaAs, InP, GaP, GaN, SiC, GaAlAs, GaInAsP, or the like can be used. Impurity diffusion layers 3 are formed in the active regions in the semiconductor substrate 1, and gate electrodes 4B, 5B are respectively formed via gate insulating films 4A, 5A on channel regions between impurity diffusion layers 3. An interlayer insulating film 6 is formed over the gate electrodes 4B, 5B, and a step DA1 is formed in the interlayer insulating film 6. As the material for the STI 2, gate insulating films 4A, 5A, and interlayer insulating film 6, for example, SiO₂ or the like can be used. As the material for the gate electrodes 4B, 5B, for example, polycrystalline silicon or the like can be used.

Meanwhile, in the photoelectric conversion unit B2, a storing electrode 7 is formed over the upper level of the interlayer insulating film 6 in such a way as to cover the step DA1. A step DA2 reflecting the step DA1 of the interlayer insulating film 6 is formed in the storing electrode 7. An insulating film 9 is formed on the storing electrode 7 and the lower level of the interlayer insulating film 6 in such a way as to cover the step DA2. The thickness of the insulating film 9 can be set at about 10 to 100 nm. A transfer electrode 10 is formed on the lower levels of the insulating film 9. Here, the gap GA along a horizontal direction between the storing electrode 7 and the transfer electrode 10 can be defined by the thickness of the insulating film 9 at the side wall of the storing electrode 7 in a self-aligned manner. At the lower level of the interlayer insulating film 6, that is, at the lower level of the storing electrode 7, the transfer electrode 10 can overlap the storing electrode 7. A contact plug 8 is embedded in the interlayer insulating film 6 and the insulating film 9 under the transfer electrode 10. And the transfer electrode 10 is connected to an impurity diffusion layer 3 which is to be a floating diffusion, described later, via the contact plug 8. Note that the difference in level of the transfer electrode 10 from the surface of the insulating film 9 can be set to be less than or equal to half of the thickness of the photoelectric conversion film 11.

The photoelectric conversion film 11 is provided on the insulating film 9 and the transfer electrode 10. That is, the storing electrode 7 is provided under part of the photoelectric conversion film 11 via the insulating film 9, and the transfer electrode 10 is provided under the other part of the photoelectric conversion film 11. Note that the upper level of the storing electrode 7 opposite the photoelectric conversion film 11 effectively functions as the portion to cause charge photoelectrically converted into in the photoelectric conversion film 11 to be stored. An upper electrode 12 is provided on the photoelectric conversion film 11. As the material for the storing electrode 7, the transfer electrode 10, and the upper electrode 12, a transparent electrode material such as ITO, SnO₂, or ZnO can be used. The materials of the storing electrode 7 and the transfer electrode 10 may be different. In this case, the storing electrode 7 can be made higher in optical transmittance for the incidence wavelength range than the transfer electrode 10. As the material for the photoelectric conversion film 11, for example, an organic film sensitive to the incidence wavelength range can be used. The material for the contact plug 8 may be, for example, impurity-doped polycrystalline silicon or metal such as Al or Cu.

And when charge is to be stored, the potentials of the upper electrode 12, the transfer electrode 10, and the storing electrode 7 are set so as to satisfy the relationship that the upper electrode 12<the transfer electrode 10<the storing electrode 7. At this time, as indicated by P1 in FIG. 1B, the potential of the photoelectric conversion film 11 is higher at positions directly above the storing electrode 7 than at positions directly above the transfer electrode 10. Then when incident light LI is incident on the photoelectric conversion film 11, the incident light LI is converted into charges e⁻ to be stored in part of the photoelectric conversion film 11 directly above the storing electrode 7.

When charge is to be transferred, the potentials of the upper electrode 12, the transfer electrode 10, and the storing electrode 7 are set so as to satisfy the relationship that the upper electrode 12<the storing electrode 7<the transfer electrode 10. At this time, as indicated by P2 in FIG. 1B, the potential of the photoelectric conversion film 11 is lower at positions directly above the storing electrode 7 than at positions directly above the transfer electrode 10. Thus, charges e⁻ stored in part of the photoelectric conversion film 11 directly above the storing electrode 7 are transferred to the transfer electrode 10 and transferred to the impurity diffusion layer 3 via the contact plug 8. At this time, if the gap GA is large, a potential barrier occurs at the boundary between the transfer electrode 10 and the storing electrode 7 as indicated by P3 in FIG. 1B, so that the transfer of charges e⁻ from the photoelectric conversion film 11 to the transfer electrode 10 becomes incomplete. On the other hand, if the gap GA is small, a potential barrier does not occur at the boundary between the transfer electrode 10 and the storing electrode 7 as indicated by P2 in FIG. 1B, so that charges e⁻ can be completely transferred from the photoelectric conversion film 11 to the transfer electrode 10. Thus, where the gap GA is small, the occurrence of a residual image and thermal noise can be reduced as compared with where the gap GA is large.

Here, by defining the gap GA between (the effectively functioning portion of) the storing electrode 7 and the transfer electrode 10 by the thickness of the insulating film 9 at the side wall of the storing electrode 7 in a self-aligned manner, the gap GA can be made smaller with suppressing variation in the gap GA as compared with where the gap GA is adjusted by mask alignment. Thus, when charge is to be transferred, a potential barrier can be prevented from occurring at the boundary between the transfer electrode 10 and the storing electrode 7, and the potential distribution indicated by P2 in FIG. 1B can be obtained.

Although FIG. 1A shows a configuration where the transfer electrode 10 overlaps the storing electrode 7, it may be a structure where the transfer electrode 10 does not overlap the storing electrode 7. Or it may be a structure where no steps are formed in the interlayer insulating film 6 and the storing electrode 7.

Charges used as a signal from among charges converted from the incident light LI may be e⁻ (electrons) as described above, or h⁺ (holes). Where charges h⁺ converted from the incident light LI are used as signal charges, the potential relationship between the upper electrode 12, the storing electrode 7, and the transfer electrode 10 are set as follows. That is, when charge is to be stored, the potentials of the upper electrode 12, the transfer electrode 10, and the storing electrode 7 are set so as to satisfy the relationship that the upper electrode 12>the transfer electrode 10>the storing electrode 7. When charge is to be transferred, the potentials of the upper electrode 12, the transfer electrode 10, and the storing electrode 7 are set so as to satisfy the relationship that the upper electrode 12>the storing electrode 7>the transfer electrode 10.

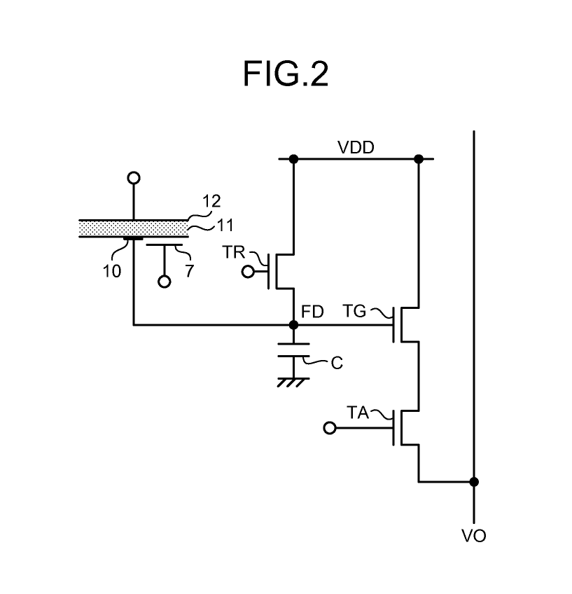

FIG. 2 is a diagram showing the circuit configuration of the pixel of the solid-state imaging device according to the first embodiment.

In FIG. 2, in the signal readout circuit B1, there are provided a row select transistor TA, an amplifying transistor TG, and a reset transistor TR. A floating diffusion FD as a detection node is formed at the connection point of the amplifying transistor TG and reset transistor TR. The floating diffusion FD is grounded via a capacitor C.

The source of the reset transistor TR is connected to the floating diffusion FD, and the drain of the reset transistor TR is connected to a power supply potential VDD. The drain of the row select transistor TA is connected to the source of the amplifying transistor TG, and the source of the row select transistor TA is connected to a vertical signal line VO. The drain of the amplifying transistor TG is connected to the power supply potential VDD, and the gate of the amplifying transistor TG is connected to the floating diffusion FD. The floating diffusion FD is connected to the transfer electrode 10. Note that the gate electrode 4B of FIG. 1A can be used for the reset transistor TR and that the gate electrode 5B of FIG. 1A can be used for the row select transistor TA.

When the reset transistor TR is turned on, the potential on the floating diffusion FD is reset. Then when the row select transistor TA is turned on, pixels along a row direction are selected. Then charges stored in the photoelectric conversion film 11 are transferred to the floating diffusion FD via the transfer electrode 10. Then the gate of the amplifying transistor TG is driven according to the potential on the floating diffusion FD at this time, so that the potential on the floating diffusion FD is reflected in the potential on the vertical signal line VO.

### Second Embodiment

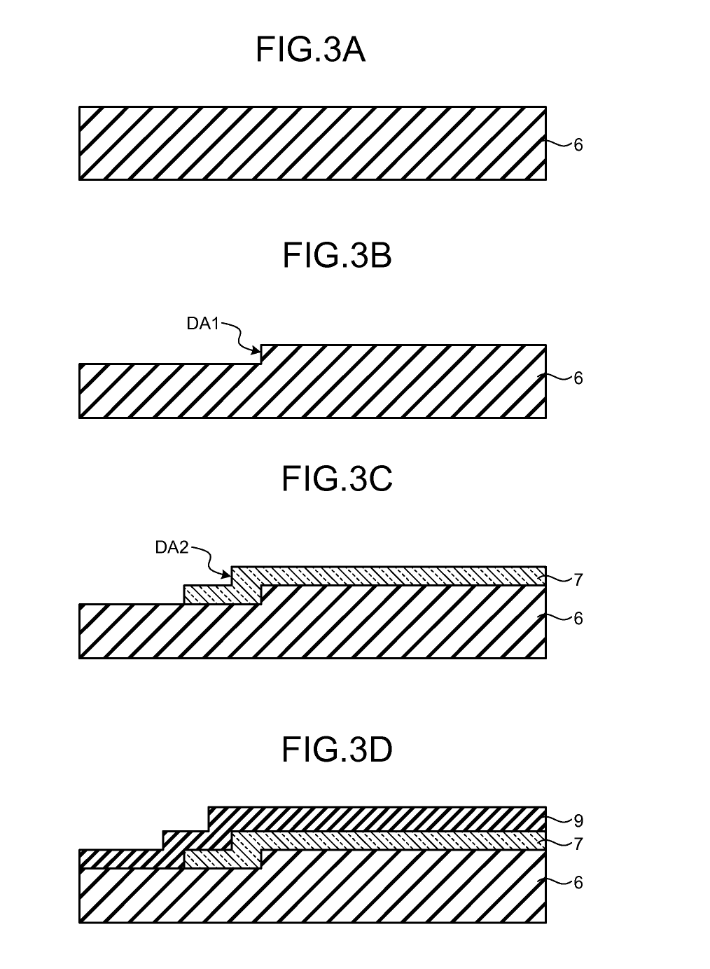

FIGS. 3A to 3D, 4A to 4C, 5A and 5B are cross-sectional views showing a manufacturing method for pixels of a solid-state imaging device according to the second embodiment. FIGS. 3A to 3D, 4A to 4C, 5A and 5B show a manufacturing method for the photoelectric conversion unit B2 of FIG. 1A.

In FIG. 3A, the interlayer insulating film 6 is formed on the semiconductor substrate 1 of FIG. 1A by a method such as CVD.

Then, as shown in FIG. 3B, by selectively making part of the interlayer insulating film 6 thinner using a photolithography technique and a dry etching technique, the step DA1 is formed in the interlayer insulating film 6. Then, as shown in FIG. 3C, a film of transparent electrode material is formed on the interlayer insulating film 6 by a method such as CVD. The film of transparent electrode material is patterned using the photolithography technique and the dry etching technique or a wet etching technique, so that the storing electrode 7 is formed on the upper level of the interlayer insulating film 6. At this time, the storing electrode 7 is placed to cover the step DA1, so that the step DA2 reflecting the step DA1 can be formed in the storing electrode 7.

Then, as shown in FIG. 3D, the insulating film 9 is formed on the storing electrode 7 and the lower level of the interlayer insulating film 6 by a method such as CVD.

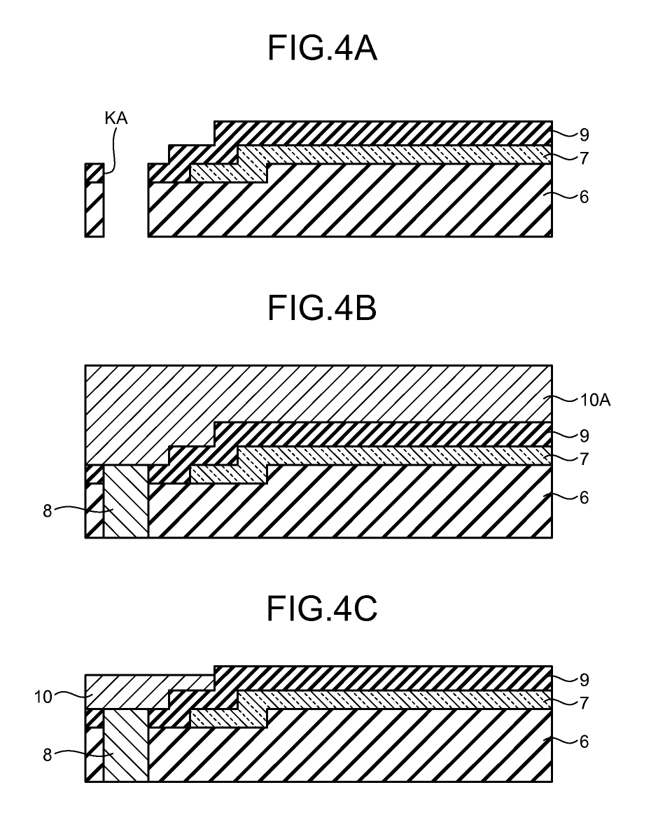

Then, as shown in FIG. 4A, the interlayer insulating film 6 and the insulating film 9 are patterned using the photolithography technique and the dry etching technique, so that an opening KA is formed in the interlayer insulating film 6 and the insulating film 9.

Then, as shown in FIG. 4B, the contact plug 8 is filled into the opening KA. Then transparent electrode material 10A is deposited on the contact plug 8 and the insulating film 9 by a method such as CVD.

Then, as shown in FIG. 4C, by making the transparent electrode material 10A so thin that the insulating film 9 is exposed by a method such as CMP, the transfer electrode 10 is formed on the contact plug 8 and the lower level of the insulating film 9.

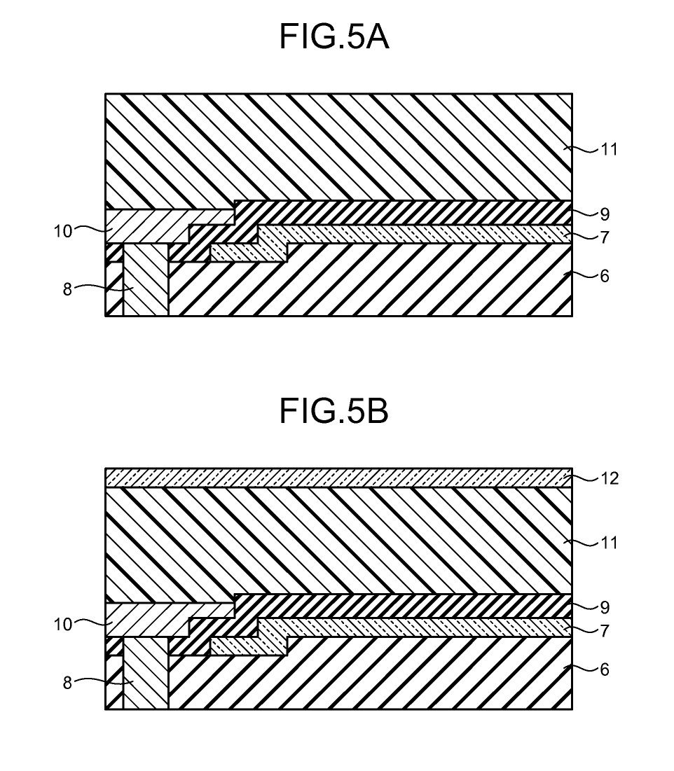

Then, as shown in FIG. 5A, the photoelectric conversion film 11 is formed on the insulating film 9 and the transfer electrode 10 by a method such as CVD.

Then, as shown in FIG. 5B, the upper electrode 12 is formed on the photoelectric conversion film 11 by a method such as CVD.

Here, by providing the step DA2 in the storing electrode 7, while the transfer electrode 10 overlaps the storing electrode 7, the gap GA between the storing electrode 7 and the transfer electrode 10 can be defined by the thickness of the insulating film 9 at the side wall of the storing electrode 7. Thus, mask alignment for defining the gap GA between the storing electrode 7 and the transfer electrode 10 is made unnecessary, so that the gap GA can be made smaller with suppressing variation in the gap GA. In this case, the thickness of the insulating film 9 can be set at about a half to one tenth of mask alignment space. Further, while mask alignment deviation is about 40 to 60 nm, variation in the thickness of the insulating film 9 can be suppressed to about 1 to 10 nm.

### Third Embodiment

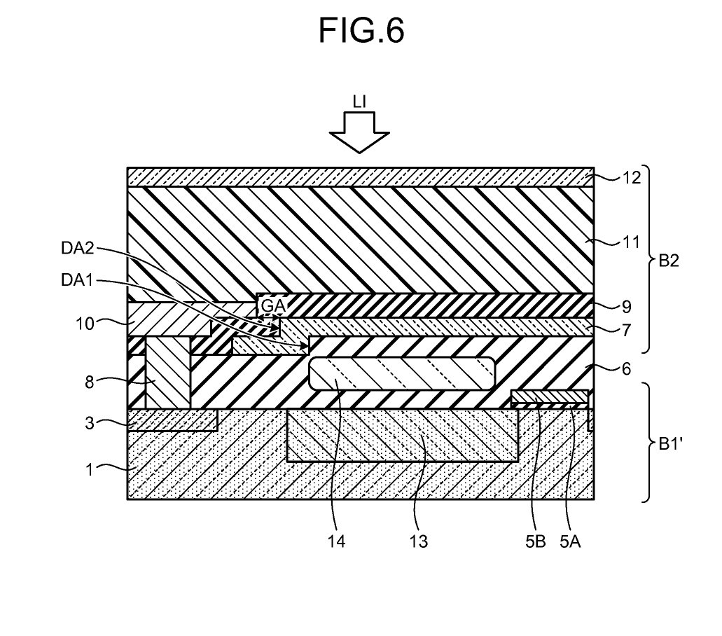

FIG. 6 is a cross-sectional view showing schematically the configuration of a pixel of a solid-state imaging device according to the third embodiment.

In FIG. 6, in this configuration, a signal readout circuit B1′ is provided instead of the signal readout circuit B1 of FIG. 1. In the signal readout circuit B1′, a photoelectric conversion layer 13 and a color filter 14 are added to the signal readout circuit B1. The photoelectric conversion layer 13 is formed in the semiconductor substrate 1. Letting the conductivity type of the semiconductor substrate 1 be P type, a photodiode is formed by setting the conductivity type of the photoelectric conversion layer 13 to be N type. The color filter 14 is placed over the photoelectric conversion layer 13. The color filter 14 can be embedded in the interlayer insulating film 6. If the pass wavelength range of the color filter 14 is set at blue or red, the photoelectric conversion film 11 can be made to have sensitivity to green.

When incident light LI is incident on the photoelectric conversion film 11, green light is converted into charges e⁻ to be stored in part of the photoelectric conversion film 11 directly above the storing electrode 7. Further, red light and blue light out of the incident light LI pass through the photoelectric conversion film 11, and the color filter 14 selects the red light or the blue light. Then the selected red light or blue light is incident on the photoelectric conversion layer 13 and converted into charges e⁻ to be stored in the photoelectric conversion layer 13.

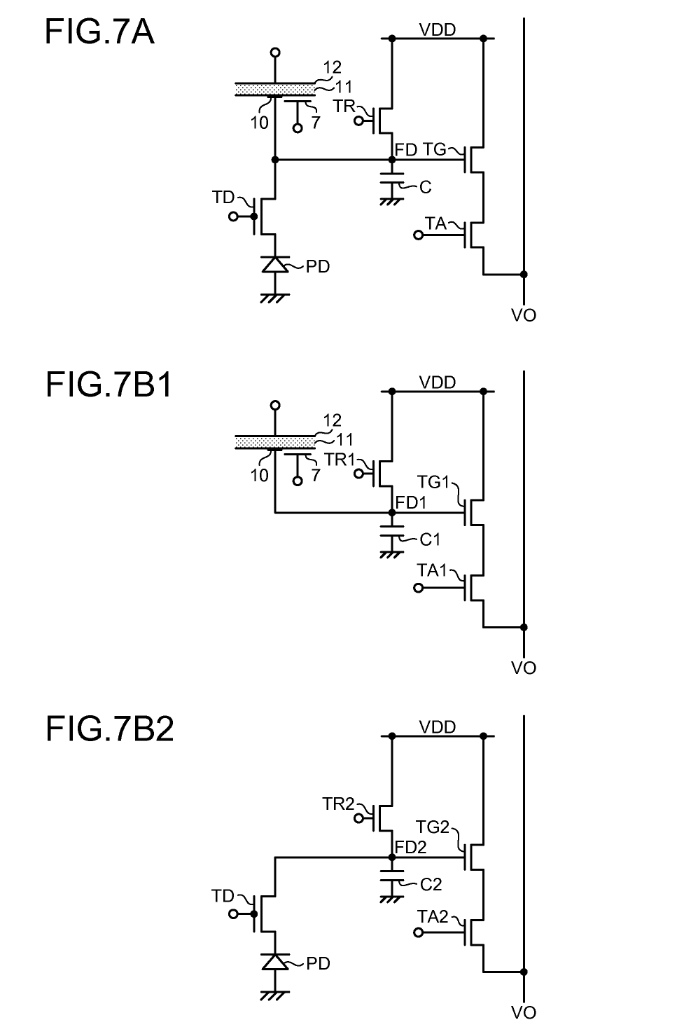

FIG. 7A is a diagram showing the circuit configuration of the pixel of the solid-state imaging device according to the third embodiment, and FIGS. 7B1 and 7B2 are diagrams showing other circuit configurations of the pixel of the solid-state imaging device according to the third embodiment.

In FIG. 7A, in the signal readout circuit B1′, a readout transistor TD and a photodiode PD are added to the signal readout circuit B1. The photodiode PD is connected to a floating diffusion FD via the readout transistor TD.

When the reset transistor TR is turned on, the potential on the floating diffusion FD is reset. Then when the row select transistor TA is turned on, pixels along a row direction are selected. Then charges stored in the photoelectric conversion film 11 are transferred to the floating diffusion FD via the transfer electrode 10. Then the gate of the amplifying transistor TG is driven according to the potential on the floating diffusion FD at this time, so that the potential on the floating diffusion FD is reflected in the potential on the vertical signal line VO, and thus the charges stored in the photoelectric conversion film 11 are read out. Thereafter, when the reset transistor TR is turned on, the potential on the floating diffusion FD is reset. Then when the readout transistor TD is turned on, charges stored in the photodiode PD are transferred to the floating diffusion FD. Then the gate of the amplifying transistor TG is driven according to the potential on the floating diffusion FD at this time, so that the potential on the floating diffusion FD is reflected in the potential on the vertical signal line VO, and thus the charges stored in the photodiode PD are read out.

In the circuit configuration of the signal readout circuit B1′, a circuit that reads a signal from the photoelectric conversion film 11 and a circuit that reads a signal from the photodiode PD may be one common circuit as shown in FIG. 7A, or the circuit that reads a signal from the photoelectric conversion film 11 and the circuit that reads a signal from the photodiode PD may be provided separately as shown in FIGS. 7B1 and 7B2.

In this case, as shown in FIG. 7B1, in the circuit that reads a signal from the photoelectric conversion film 11, there are provided a row select transistor TA1, an amplifying transistor TG1, and a reset transistor TR1. A floating diffusion FD1 is grounded via a capacitor C1. In the circuit that reads a signal from the photodiode PD, as shown in FIG. 7B2, there are provided the readout transistor TD, a row select transistor TA2, an amplifying transistor TG2, and a reset transistor TR2. A floating diffusion FD2 is grounded via a capacitor C2.

By laying the photoelectric conversion film 11 over the photodiode PD, the areas of the photodiode PD and the photoelectric conversion film 11 in each pixel can be increased. Thus, the sensitivity of the solid-state imaging device can be improved without an increase in chip size.

Further, because the color filter 14 is embedded in the interlayer insulating film 6, also where the photoelectric conversion film 11 is laid over the photodiode PD, the gap GA between the storing electrode 7 and the transfer electrode 10 can be defined by the thickness of the insulating film 9 at the side wall of the storing electrode 7 in a self-aligned manner. Thus, when charge is to be transferred, a potential barrier can be prevented from occurring at the boundary between the transfer electrode 10 and the storing electrode 7, so that the image quality can be improved.

### Fourth Embodiment

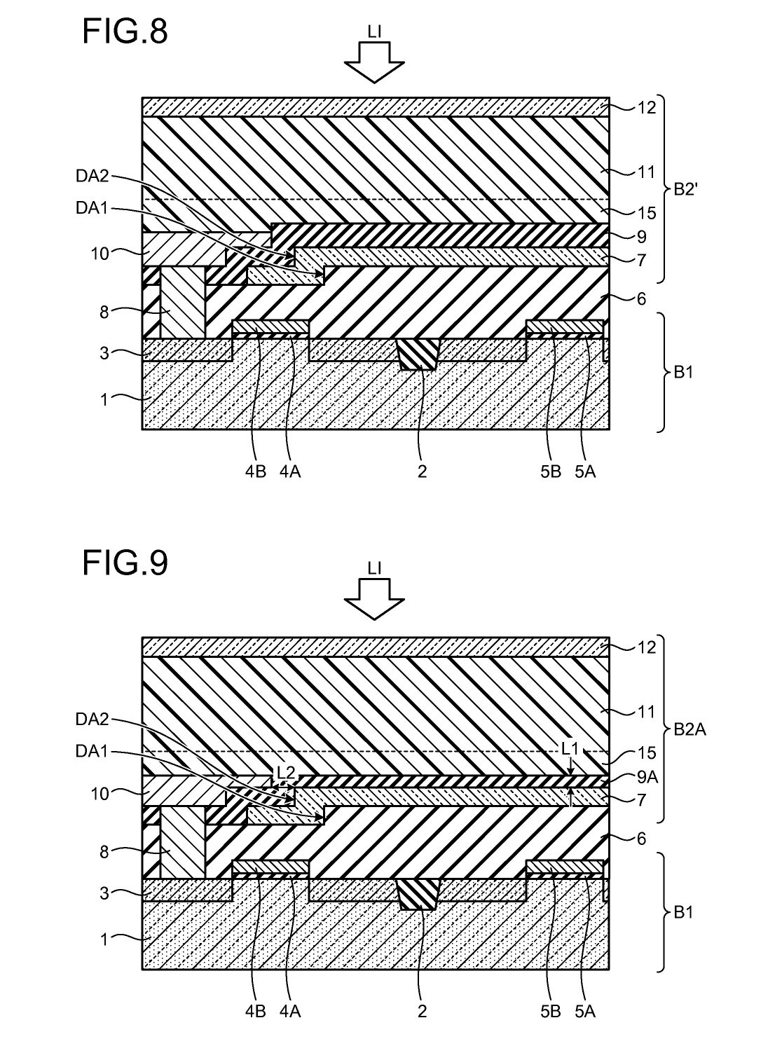

FIG. 8 is a cross-sectional view showing schematically the configuration of a pixel of a solid-state imaging device according to the fourth embodiment.

In FIG. 8, in this configuration, a photoelectric conversion unit B2′ is provided instead of the photoelectric conversion unit B2 of FIG. 1. In the photoelectric conversion unit B2′, an organic film 15 is added to the photoelectric conversion unit B2. The organic film 15 is higher in charge mobility than the photoelectric conversion film 11. The organic film 15 is placed on the insulating film 9 and the transfer electrode 10, and the photoelectric conversion film 11 is placed on the organic film 15.

And when charge is to be stored, the potentials of the upper electrode 12, the transfer electrode 10, and the storing electrode 7 are set so as to satisfy the relationship that the upper electrode 12<the transfer electrode 10<the storing electrode 7. Then when incident light LI is incident on the photoelectric conversion film 11, the incident light LI is converted into charges e⁻ to be stored in part of the organic film 15 directly above the storing electrode 7.

When charge is to be transferred, the potentials of the upper electrode 12, the transfer electrode 10, and the storing electrode 7 are set so as to satisfy the relationship that the upper electrode 12<the storing electrode 7<the transfer electrode 10. Then charges e⁻ stored in part of the organic film 15 directly above the storing electrode 7 are transferred to the transfer electrode 10 and transferred to the impurity diffusion layer 3 via the contact plug 8.

Where the organic film 15 is under the photoelectric conversion film 11, the charge transfer time can be shortened as compared with where there is not the organic film 15. Thus, signal readout can be speeded up, and the frame rate can be raised.

Note that in the photoelectric conversion unit B2′ a film of high charge mobility made of another material such as an oxide semiconductor may be provided instead of the organic film 15. Charges used as a signal from among charges converted from the incident light LI may be e⁻ (electrons) or h⁺ (holes).

### Fifth Embodiment

FIG. 9 is a cross-sectional view showing schematically the configuration of a pixel of a solid-state imaging device according to the fifth embodiment.

In FIG. 9, in this configuration, a photoelectric conversion unit B2A is provided instead of the photoelectric conversion unit B2′ of FIG. 8. In the photoelectric conversion unit B2A, an insulating film 9A is provided instead of the insulating film 9. The thickness L1 of the insulating film 9A on the storing electrode 7 is smaller than the thickness L2 at the side wall of the storing electrode 7. By making the thickness L1 of the insulating film 9A on the storing electrode 7 smaller, the capacitance of the storing electrode 7 can be increased. Hence, the amount of charge stored in the photoelectric conversion unit B2A can be increased, and the saturated signal amount can be increased. As an example of the method of making the thickness L1 of the insulating film 9A on the storing electrode 7 smaller than the thickness L2 of the insulating film 9A at the side wall of the storing electrode 7, a method which etches back the insulating film 9A on the storing electrode 7 by a method such as CMP can be cited.

### Sixth Embodiment

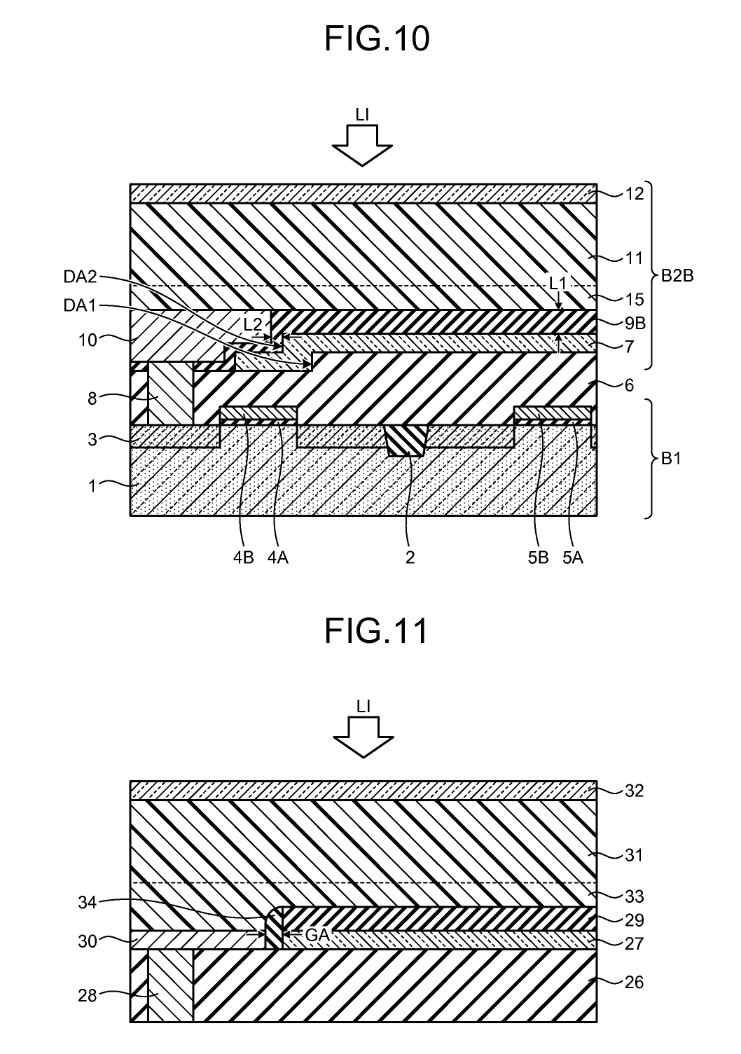

FIG. 10 is a cross-sectional view showing schematically the configuration of a pixel of a solid-state imaging device according to the sixth embodiment.

In FIG. 10, in this configuration, a photoelectric conversion unit B2B is provided instead of the photoelectric conversion unit B2′ of FIG. 8. In the photoelectric conversion unit B2B, an insulating film 9B is provided instead of the insulating film 9. The thickness L2 of the insulating film 9B at the side wall of the storing electrode 7 is smaller than the thickness L1 thereof on the storing electrode 7. By making the thickness L2 at the side wall of the storing electrode 7 smaller, the gap GA between the storing electrode 7 and the transfer electrode 10 can be made smaller. Hence, when charge is to be transferred, in order to prevent a potential barrier from occurring at the boundary between the transfer electrode 10 and the storing electrode 7, the voltage applied to the storing electrode 7 can be decreased, so that power consumption can be reduced.

Note that as an example of the method of making the thickness L2 of the insulating film 9B at the side wall of the storing electrode 7 smaller than the thickness L1 of the insulating film 9B on the storing electrode 7, a method which forms the insulating film 9B under film-formation conditions which result in poor step coverage can be cited. Although FIGS. 8 to 10 show configurations where the signal readout circuit B1 of FIG. 1A is provided, the signal readout circuit B1′ of FIG. 6 may be provided.

Further, in FIGS. 9 and 10, the photoelectric conversion film 11 may be formed alone without adding the organic film 15 to the photoelectric conversion units B2A, B2B as in the photoelectric conversion unit B2 of FIG. 1A.

### Seventh Embodiment

FIG. 11 is a cross-sectional view showing schematically the configuration of a pixel of a solid-state imaging device according to the seventh embodiment. Note that in FIG. 11 the signal readout circuit B1 of FIG. 1A is omitted.

In FIG. 11, a storing electrode 27 is formed on an interlayer insulating film 26, and an insulating film 29 is formed over the storing electrode 27. A side-wall insulating film 34 is formed on the side walls of the storing electrode 27 and of the insulating film 29. The thickness of the side-wall insulating film 34 can be set at about 10 to 100 nm. A transfer electrode 30 is formed adjacent to the storing electrode 27 with the side-wall insulating film 34 being in between on the interlayer insulating film 26. Here, the gap GA along a horizontal direction between the storing electrode 27 and the transfer electrode 30 can be defined by the thickness of the side-wall insulating film 34 in a self-aligned manner. A contact plug 28 is embedded in the interlayer insulating film 26 under the transfer electrode 30. A photoelectric conversion film 31 is provided over the insulating film 29, the side-wall insulating film 34, and the transfer electrode 30.

That is, the storing electrode 27 is provided under part of the photoelectric conversion film 31 via the insulating film 29, and the transfer electrode 30 is provided under the other part of the photoelectric conversion film 31. An upper electrode 32 is provided over the photoelectric conversion film 31. In the photoelectric conversion unit, an organic film 33 of higher charge mobility than the photoelectric conversion film 31 may be used together with the photoelectric conversion film 31 as shown in FIG. 11, or the photoelectric conversion film 31 may be formed alone as in the photoelectric conversion unit B2 of FIG. 1A.

Here, by defining the gap GA between the storing electrode 27 and the transfer electrode 30 by the thickness of the side-wall insulating film 34 in a self-aligned manner, the gap GA can be made smaller with suppressing variation in the gap GA as compared with where the gap GA is adjusted by mask alignment. Further, because the side-wall insulating film 34 is formed on the side walls of the storing electrode 27 and of the insulating film 29, a step need not be provided in the interlayer insulating film 26 to form the insulating film on the side wall of the storing electrode 27, and thus the time required to process the interlayer insulating film 26 can be eliminated. The thickness of the insulating film 29 on the storing electrode 27 may be smaller than that of the side-wall insulating film 34 on the storing electrode 27 as in FIG. 9, or greater than that of the side-wall insulating film 34 on the storing electrode 27 as in FIG. 10.

### Eighth Embodiment

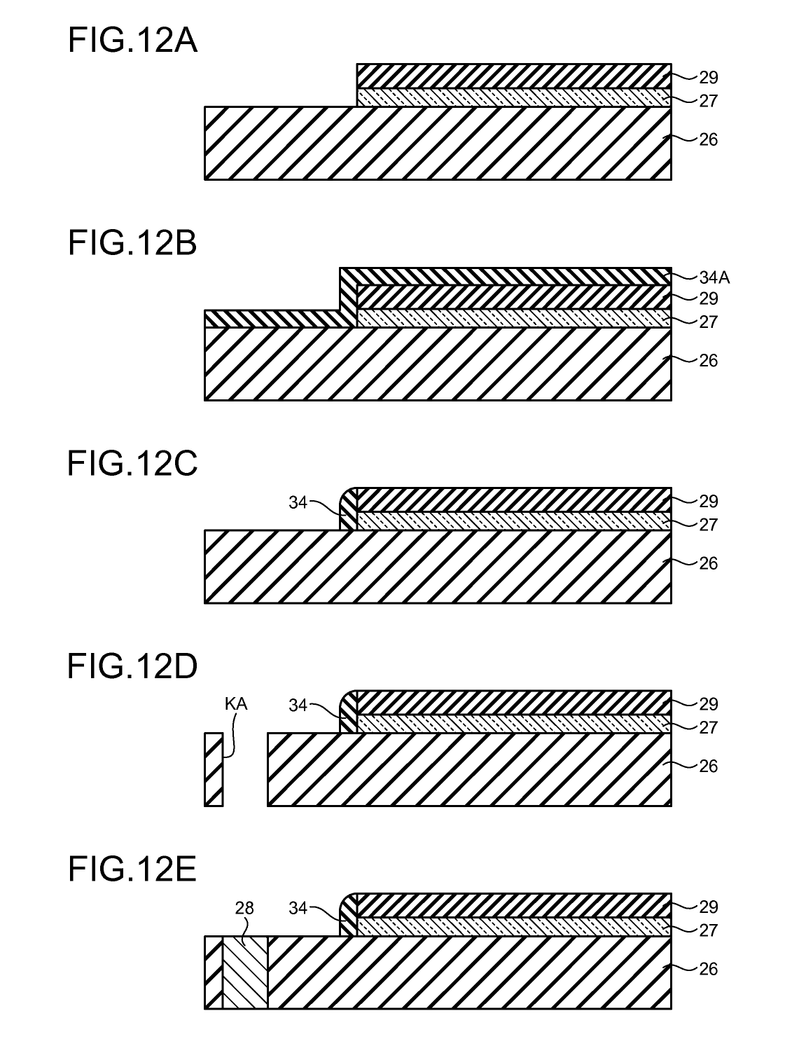

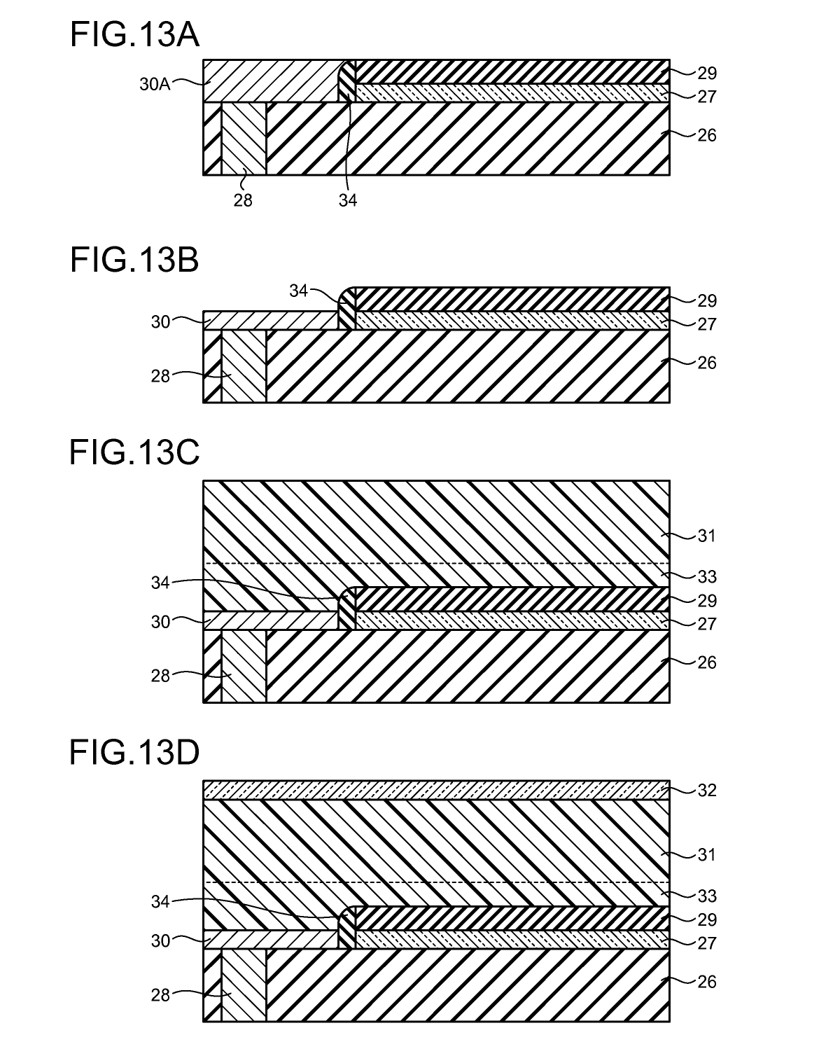

FIGS. 12A to 12E and 13A to 13D are cross-sectional views showing a manufacturing method for pixels of a solid-state imaging device according to the eighth embodiment.

In FIG. 12A, films of transparent electrode material and insulating material are formed on the interlayer insulating film 26 by a method such as CVD. The films of transparent electrode material and insulating material are patterned using the photolithography technique and the dry etching technique, so that the storing electrode 27 and the insulating film 29 are formed. Then, as shown in FIG. 12B, insulating material 34A is deposited on the interlayer insulating film 26 and the insulating film 29 by a method such as CVD.

Then, as shown in FIG. 12C, by making the insulating material 34A so thin that the interlayer insulating film 26 is exposed by anisotropic etching, the side-wall insulating film 34 is formed on the side walls of the storing electrode 27 and of the insulating film 29.

Then, as shown in FIG. 12D, the interlayer insulating film 26 is patterned using the photolithography technique and the dry etching technique, so that an opening KA is formed in the interlayer insulating film 26. Then, as shown in FIG. 12E, the contact plug 28 is filled into the opening KA.

Then, as shown in FIG. 13A, transparent electrode material 30A is deposited on the interlayer insulating film 26, the insulating film 29, the contact plug 28, and the side-wall insulating film 34 by a method such as CVD. Then the transparent electrode material 30A is flattened by a method such as CMP.

Then, as shown in FIG. 13B, by selectively making the transparent electrode material 30A thinner by a method such as anisotropic etching, the transfer electrode 30 is formed on the interlayer insulating film 26 and the contact plug 28.

Then, as shown in FIG. 13C, the photoelectric conversion film 31 is formed on the insulating film 29, the side-wall insulating film 34, and the transfer electrode 30 by a method such as CVD. At this time, the organic film 33 of higher charge mobility than the photoelectric conversion film 31 may be formed.

Then, as shown in FIG. 13D, the upper electrode 32 is formed on the photoelectric conversion film 31 by a method such as CVD.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A solid-state imaging device comprising:
a photoelectric conversion film provided over a semiconductor substrate;
a storing electrode provided under part of the photoelectric conversion film;
a first insulating film provided between the photoelectric conversion film and the storing electrode;
a transfer electrode provided under the other part of the photoelectric conversion film;
an upper electrode provided over the photoelectric conversion film; and
a second insulating film provided on a side wall of the storing electrode,
wherein a gap along a horizontal direction between the storing electrode and the transfer electrode is defined by a thickness of the second insulating film.

2. The solid-state imaging device of claim 1, wherein the storing electrode is higher in optical transmittance for an incidence wavelength range than the transfer electrode.

3. The solid-state imaging device of claim 1, further comprising a film provided under the photoelectric conversion film and higher in charge mobility than the photoelectric conversion film.

4. The solid-state imaging device of claim 1, wherein the first insulating film is thicker in thickness than the second insulating film.

5. The solid-state imaging device of claim 1, wherein the first insulating film is thinner in thickness than the second insulating film.

6. The solid-state imaging device of claim 1, further comprising a floating diffusion coupled to the transfer electrode and provided in the semiconductor substrate.

7. The solid-state imaging device of claim 1, further comprising a photodiode provided in the semiconductor substrate,
wherein the photoelectric conversion film is laid over the photodiode.

8. A solid-state imaging device comprising:
a photoelectric conversion film provided over a semiconductor substrate;
a storing electrode provided under part of the photoelectric conversion film;
an insulating film provided under the photoelectric conversion film so as to cover a top and a side wall of the storing electrode;
a transfer electrode provided between the other part of the photoelectric conversion film and the insulating film; and
an upper electrode provided over the photoelectric conversion film.

9. The solid-state imaging device of claim 8, wherein a step is provided in the storing electrode.

10. The solid-state imaging device of claim 9, wherein the storing electrode is provided under the insulating film, and the transfer electrode is provided on the insulating film.

11. The solid-state imaging device of claim 10, wherein the transfer electrode overlaps a lower level of the storing electrode.

12. The solid-state imaging device of claim 8, wherein the storing electrode is higher in optical transmittance for an incidence wavelength range than the transfer electrode.

13. The solid-state imaging device of claim 8, further comprising a film provided under the photoelectric conversion film and higher in charge mobility than the photoelectric conversion film.

14. The solid-state imaging device of claim 8, wherein a thickness of the insulating film is greater at the side wall of the storing electrode than on the top of the storing electrode.

15. The solid-state imaging device of claim 8, wherein a thickness of the insulating film is smaller at the side wall of the storing electrode than on the top of the storing electrode.

16. The solid-state imaging device of claim 8, further comprising a floating diffusion coupled to the transfer electrode and provided in the semiconductor substrate.

17. The solid-state imaging device of claim 8, further comprising a photodiode provided in the semiconductor substrate,
wherein the photoelectric conversion film is laid over the photodiode.

18. A method of manufacturing a solid-state imaging device, comprising:
forming a storing electrode over a semiconductor substrate;
forming an insulating film on a side wall of the storing electrode;
forming a transfer electrode separated from the storing electrode by the insulating film;
forming a photoelectric conversion film over the storing electrode and the transfer electrode; and
forming an upper electrode over the photoelectric conversion film.

19. The method of manufacturing the solid-state imaging device of claim 18, wherein the storing electrode comprises a step.

20. The method of manufacturing the solid-state imaging device of claim 19, wherein the storing electrode is placed under the insulating film, and the transfer electrode is placed on the insulating film.
